(19) United States
(12) Patent Application Publication
(10) Pub. No.: US 2025/0311467 A1
(43) Pub. Date: Oct. 2, 2025

(54) SEMICONDUCTOR APPARATUS, EQUIPMENT, SEMICONDUCTOR WAFER, AND METHOD FOR MANUFACTURING SEMICONDUCTOR APPARATUS

(71) Applicant: CANON KABUSHIKI KAISHA, Tokyo (JP)

(72) Inventors: KOJI HARA, Chiba (JP); MAYU ISHIKAWA, Kanagawa (JP); AKIRA MATSUZAKI, Kanagawa (JP)

(21) Appl. No.: 19/082,474

(22) Filed: Mar. 18, 2025

(30) Foreign Application Priority Data
Mar. 26, 2024 (JP) 2024-050286
Jan. 15, 2025 (JP) 2025-005451

(51) Int. Cl. H10F 39/95; H01L 23/00; H10F 39/00

(52) U.S. Cl. CPC H10F 39/95; H01L 24/08; H01L 2224/08145; H10F 39/8053; H10F 39/8063

(57) ABSTRACT

A semiconductor apparatus includes a first semiconductor substrate, a second semiconductor substrate, and at least one semiconductor chip. The at least one semiconductor chip is bonded to the first semiconductor substrate so as to protrude from a first main surface of the first semiconductor substrate. The second semiconductor substrate having at least one recess is bonded to at least one of a part of the first main surface and the at least one semiconductor chip. The at least one semiconductor chip is disposed in the at least one recess. The at least one semiconductor chip is connected to the second semiconductor substrate via a wiring included in the first semiconductor substrate.

### BACKGROUND OF THE INVENTION

### Field of the Invention

The present invention relates to a semiconductor apparatus, a method for manufacturing a semiconductor apparatus, and the like.

### Description of the Related Art

In recent years, downsizing and performance improvement of semiconductor apparatuses have been achieved by stacking a plurality of chips provided with semiconductor elements. JP 2022-089275 A proposes a technology related to a chip on wafer (CoW) in which a chip on which a circuit such as a signal processing circuit or a memory circuit is formed and a wafer on which an imaging element is formed are bonded using Cu—Cu bonding.

An imaging apparatus described in JP 2022-089275 A has a structure in which the chip on which the circuit such as the signal processing circuit or the memory circuit is formed is bonded to the imaging element in a state of being embedded in an oxide film functioning as an insulating film. Since the chip and the imaging element are surrounded by the oxide film having a low thermal conductivity, heat generated in the circuit is likely to be trapped, and thus, there is a possibility of occurrence of adverse effects on image quality of the imaging apparatus such as deterioration in low-light performance.

### SUMMARY OF THE INVENTION

According to a first aspect of the present invention, a semiconductor apparatus includes a first semiconductor substrate, a second semiconductor substrate, and at least one semiconductor chip. The at least one semiconductor chip is bonded to the first semiconductor substrate so as to protrude from a first main surface of the first semiconductor substrate. The second semiconductor substrate having at least one recess is bonded to at least one of a part of the first main surface and the at least one semiconductor chip. The at least one semiconductor chip is disposed in the at least one recess. The at least one semiconductor chip is connected to the second semiconductor substrate via a wiring included in the first semiconductor substrate.

According to a second aspect of the present invention, a semiconductor wafer includes a wiring. At least one semiconductor chip is bonded to the semiconductor wafer so as to protrude from a main surface of the semiconductor wafer. A second semiconductor substrate having at least one recess is bonded to at least one of a part of the main surface and the at least one semiconductor chip. The at least one semiconductor chip is disposed in the at least one recess. The at least one semiconductor chip is connected to the second semiconductor substrate via the wiring included in the semiconductor wafer.

According to a third aspect of the present invention, a method for manufacturing a semiconductor apparatus includes a first bonding step of bonding at least one semiconductor chip to a first semiconductor substrate so as to protrude from a first main surface of the first semiconductor substrate, a step of forming at least one recess in a second semiconductor substrate, and a second bonding step of bonding the second semiconductor substrate to at least one of a part of the first main surface and the at least one semiconductor chip in a state in which the first semiconductor substrate and the second semiconductor substrate are aligned such that the at least one semiconductor chip bonded to the first semiconductor substrate is disposed in the at least one recess. In the second bonding step, the at least one semiconductor chip is connected to the second semiconductor substrate via a wiring included in the first semiconductor substrate.

Further features of the present invention will become apparent from the following description of exemplary embodiments with reference to the attached drawings.

### BRIEF DESCRIPTION OF THE DRAWINGS

FIG. 1A is a plan view schematically illustrating a semiconductor apparatus according to a first embodiment in plan view (perspective view).

FIG. 1B is a schematic cross-sectional view illustrating a cross section of the semiconductor apparatus taken along line A-B illustrated in FIG. 1A.

FIG. 2A is a schematic cross-sectional view illustrating cross sections of an imaging element and a circuit portion that are bonded to each other, taken along a direction perpendicular to a main surface (for example, a light receiving surface) of the imaging element.

FIG. 2B is a schematic cross-sectional view illustrating a cross section of a support substrate in which a recess is formed.

FIG. 3A is a schematic cross-sectional view illustrating a state in which a chip on wafer (CoW) structure and the support substrate are bonded to each other.

FIG. 3B is a schematic cross-sectional view illustrating a state in which an optical structure is formed.

FIG. 4 is a plan view schematically illustrating a semiconductor apparatus according to a second embodiment in plan view (perspective view).

FIG. 5A is a plan view schematically illustrating a semiconductor apparatus according to a third embodiment in plan view (perspective view).

FIG. 5B is a schematic cross-sectional view illustrating a cross section of the semiconductor apparatus taken along line A-B illustrated in FIG. 5A.

FIG. 6A is a view for describing a manufacturing process for the semiconductor apparatus according to the third embodiment.

FIG. 6B is a view for describing another manufacturing process for the semiconductor apparatus according to the third embodiment.

FIG. 7A is a plan view schematically illustrating a semiconductor apparatus according to a fourth embodiment in plan view (perspective view).

FIG. 7B is a schematic cross-sectional view illustrating a cross section of the semiconductor apparatus taken along line A-B illustrated in FIG. 7A.

FIG. 8A is a schematic cross-sectional view illustrating cross sections of an imaging element and a circuit portion that are bonded to each other, taken along a direction perpendicular to a main surface (for example, a light receiving surface) of the imaging element.

FIG. 8B is a schematic cross-sectional view illustrating a cross section of a support substrate in which a recess is formed.

FIG. 9A is a schematic cross-sectional view illustrating a state in which a CoW structure and the support substrate are bonded to each other.

FIG. 9B is a schematic cross-sectional view illustrating a state in which an optical structure is formed.

FIG. 10A is a schematic cross-sectional view illustrating a cross section of a semiconductor apparatus according to another aspect of the fourth embodiment.

FIG. 10B is a schematic cross-sectional view illustrating a cross section of a semiconductor apparatus according to still another aspect of the fourth embodiment.

FIG. 11A is a plan view schematically illustrating the semiconductor apparatus in which a plurality of chips are bonded in plan view (perspective view) in the first embodiment.

FIG. 11B is a schematic cross-sectional view illustrating a cross section of the semiconductor apparatus taken along line A-B illustrated in FIG. 11A.

FIG. 12A is a plan view schematically illustrating a semiconductor apparatus according to a fifth embodiment in plan view (perspective view).

FIG. 12B is a schematic cross-sectional view illustrating a cross section of the semiconductor apparatus taken along line A-B illustrated in FIG. 12A.

FIG. 13A is a schematic diagram for describing equipment according to a sixth embodiment.

FIG. 13B is a schematic diagram illustrating an example of a photoelectric conversion system according to the sixth embodiment.

FIG. 13C is a schematic diagram illustrating an example of an in-vehicle photoelectric conversion system according to the sixth embodiment.

### DESCRIPTION OF THE EMBODIMENTS

Semiconductor apparatuses (solid-state imaging apparatuses), methods for manufacturing a semiconductor apparatus, and the like according to embodiments of the present invention will be described with reference to the drawings. The embodiments described below are merely examples, and for example, detailed configurations can be appropriately changed and implemented by those skilled in the art without departing from the gist of the present invention.

In the drawings referred to in the following embodiments and description, elements denoted by the same reference signs have similar functions unless otherwise specified. In the drawings, in a case where a plurality of the same elements are arranged, reference signs and a description thereof may be omitted. Note that seeing through the semiconductor apparatus from a direction (Z direction) perpendicular to a main surface of a semiconductor layer may be referred to as a plan view of the semiconductor apparatus.

In addition, the drawings may be schematic for convenience of illustration and description, and thus, the shape, size, arrangement, and the like of elements in the drawings may not strictly match those of actual ones. In addition, “XX or more and YY or less” or “XX to YY” representing a numerical range means a numerical range including end points XX (lower limit) and YY (upper limit) unless otherwise specified. When numerical ranges are described in stages, the upper limit and the lower limit of each numerical range can be arbitrarily combined.

Further, in the following description, for example, a +X direction indicates the same direction as that indicated by an X-axis arrow in the illustrated coordinate system, and a −X direction indicates a direction 180 degrees opposite to that indicated by the X-axis arrow in the illustrated coordinate system. In addition, a direction simply referred to as an X direction is a direction parallel to an X-axis regardless of a difference from the direction indicated by the illustrated X-axis arrow. The same applies to directions other than the X direction.

### First Embodiment

### Configuration of Semiconductor Apparatus

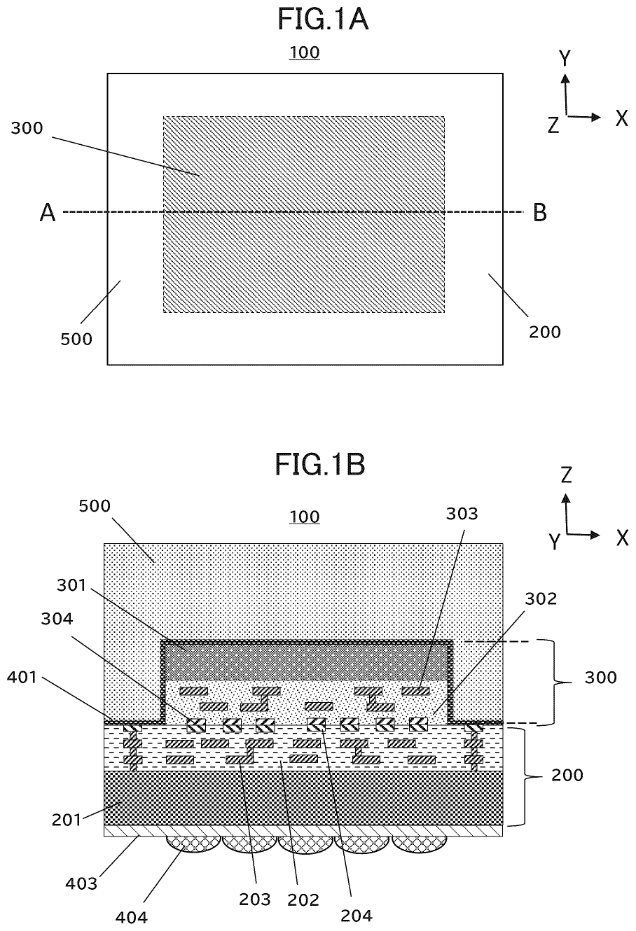

A semiconductor apparatus according to a first embodiment will be described with reference to the drawings. FIG. 1A is a plan view schematically illustrating a semiconductor apparatus 100 according to the present embodiment in plan view (perspective view) when viewed from the Z direction perpendicular to a main surface of the semiconductor apparatus 100. FIG. 1B is a schematic cross-sectional view illustrating a cross section of the semiconductor apparatus 100 taken along line A-B illustrated in FIG. 1A.

The semiconductor apparatus 100 is a back-illuminated stacked sensor using a chip on wafer (CoW) technology, and an imaging element 200 (first semiconductor substrate), a circuit portion 300 (semiconductor chip), and a support substrate 500 (second semiconductor substrate) are integrated with one another.

The imaging element 200 includes a first semiconductor layer 201, an interlayer wiring film 202 (interlayer insulating film), and a wiring layer 203. For example, a photodiode (not illustrated) serving as a photoelectric conversion unit is formed in the first semiconductor layer 201, and the interlayer wiring film 202 and the wiring layer 203 are stacked on the first semiconductor layer 201. A metal layer 204 electrically connected to the wiring layer 203 is disposed on an upper surface (a surface opposite to the first semiconductor layer 201) of the interlayer wiring film 202. The metal layer 204 contains, for example, copper as a main component, and the interlayer wiring film 202 contains, for example, silicon oxide as a main component. Note that the main component is a component having the largest weight when there are a plurality of components (materials) contained in a member, and in the present specification, the largest weight means that the component occupies 50 wt. % or more. Optical structures such as a color filter 403 and a microlens 404 are disposed on a light receiving surface side (a lower side in FIG. 1B) of the imaging element 200.

The circuit portion 300 includes a second semiconductor layer 301, an interlayer wiring film 302 (interlayer insulating film), and a wiring layer 303. The circuit portion 300 includes at least some of a drive circuit that drives the imaging element 200 to read a signal, a control circuit, a signal processing circuit, an output circuit, and the like. A metal layer 304 electrically connected to the wiring layer 303 is disposed on a lower surface (a surface adjacent to the first semiconductor layer 201) of the interlayer wiring film 302. The metal layer 304 contains, for example, copper as a main component, and the interlayer wiring film 302 contains, for example, silicon oxide as a main component.

The imaging element 200 and the circuit portion 300 are bonded to each other. That is, the metal layer 204 and the metal layer 304 are bonded by metal bonding of Cu—Cu, and the interlayer wiring film 202 and the interlayer wiring film 302 are bonded by covalent bonding of silicon oxide. As the metal layer 204 and the metal layer 304 are bonded to each other, a wiring included in the imaging element 200 and a wiring included in the circuit portion 300 are electrically connected to form an electric circuit network of the semiconductor apparatus 100.

If the imaging element 200 is referred to as a wafer and the circuit portion 300 is referred to as a chip, a chip on wafer (CoW) structure in which the chip is disposed on the wafer having a relatively large area in plan view is formed. In other words, the chip having a relatively small area in plan view is stacked on a main surface of the wafer, and the chip forms a protrusion protruding from the main surface of the wafer.

The support substrate 500 is a substrate made of a material having a higher thermal conductivity than an insulator such as silicon oxide, and for example, a semiconductor substrate such as silicon is used. A silicide layer having a high thermal conductivity may be provided on a surface of the support substrate 500, and for example, a material having a thermal conductivity of 100 W/m²·K or higher may be used. The support substrate 500 is provided with a recess corresponding to a shape of the circuit portion 300 protruding from a main surface of the imaging element 200, and the circuit portion 300, which is a protrusion, is disposed in the recess of the support substrate 500.

The support substrate 500 supports both the imaging element 200 (wafer) and the circuit portion 300 (chip). A bonding layer 401 is disposed between the support substrate 500 and the imaging element 200 and between the support substrate 500 and the circuit portion 300, and the support substrate 500 and the CoW structure are bonded via the bonding layer 401. It is desirable that the bonding layer 401 has a thickness of, for example, 3 μm or less in order not to hinder heat dissipation from the circuit portion 300 or the imaging element 200 to the support substrate 500.

As illustrated in FIG. 1A, the support substrate 500 has a larger area than the circuit portion 300 (chip) in plan view of the semiconductor apparatus 100 when viewed from a direction (that is, the Z direction) perpendicular to a main surface of the first semiconductor layer 201 or the second semiconductor layer 301. The circuit portion 300 is surrounded by the support substrate 500 in plan view. In a cross section in a direction perpendicular to the main surface of the first semiconductor layer 201 or the second semiconductor layer 301 as illustrated in FIG. 1B, one main surface (a main surface opposite to the imaging element 200) and side surfaces of the circuit portion 300 face the support substrate 500 with the bonding layer 401 having a small thickness interposed therebetween. That is, the circuit portion 300 is surrounded by the support substrate 500 having a higher thermal conductivity than the insulator except for a surface that is in contact with (bonded to) the imaging element 200. Furthermore, the imaging element 200 faces the support substrate 500 having a higher thermal conductivity than the insulator with the bonding layer 401 having a small thickness interposed therebetween in the periphery of the circuit portion 300 in plan view.

According to the present embodiment having such a structure, heat generated by the circuit portion 300 (chip) can be more efficiently dissipated through the support substrate 500 as compared with a case where the circuit portion 300 (chip), which is a heat generating body, is embedded in the insulator as in the related art. In addition, it is possible to efficiently dissipate heat also from the imaging element 200 to the support substrate 500. That is, it is possible to implement a structure in which heat generated by a circuit hardly accumulates in a semiconductor apparatus in which a plurality of semiconductor substrates provided with semiconductor elements are bonded to each other, and it is possible to effectively suppress occurrence of adverse effects on image quality of an imaging apparatus such as deterioration in low-light performance.

In the above description, the semiconductor apparatus 100 in which one circuit portion (chip) is bonded to one imaging element (wafer) has been described as an example, but the present embodiment is not limited thereto. The present embodiment may be implemented as, for example, an imaging apparatus in which two or more circuit portions (chips) are bonded to one imaging element (wafer).

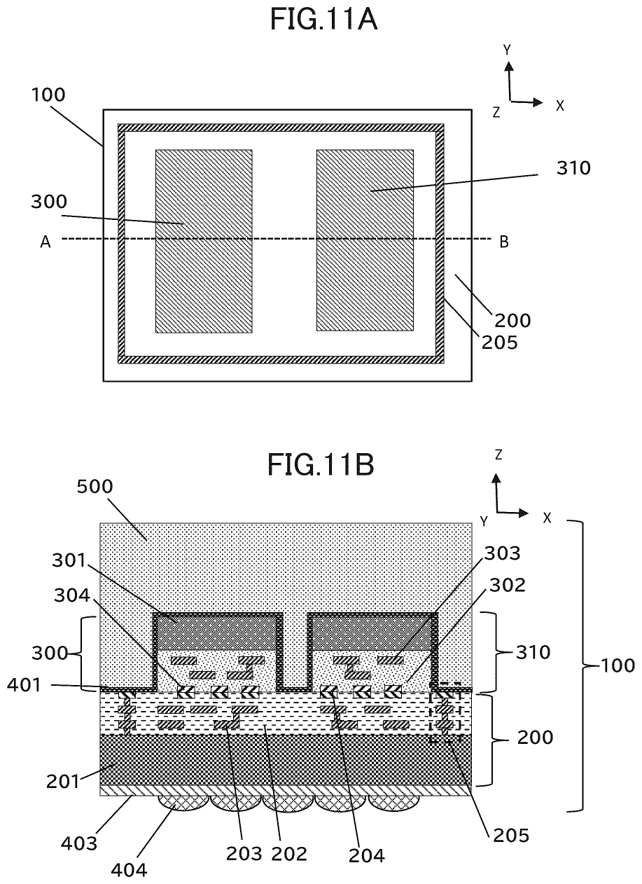

FIG. 11A is a plan view schematically illustrating the semiconductor apparatus 100 in which two chips of the circuit portion 300 and a circuit portion 310 are bonded to the imaging element 200 (wafer) in plan view (perspective view) from the Z direction perpendicular to the main surface. FIG. 11B is a schematic cross-sectional view illustrating a cross section of the semiconductor apparatus 100 taken along line A-B illustrated in FIG. 11A. Note that the imaging element 200 included in the semiconductor apparatus 100 includes a first guard portion 205. The first guard portion 205 has a function of suppressing entry of moisture from the outside of the imaging element 200 to the inside of the imaging element 200. As illustrated in FIG. 11A, the first guard portion 205 is disposed along an outer periphery of the imaging element 200 in plan view.

In this case, recesses corresponding to the shapes of the respective circuit portions (chips) are formed in the support substrate 500 made of a material having a higher thermal conductivity than the insulator, and the semiconductor apparatus can be configured such that each circuit portion is surrounded by the support substrate 500. As a result, it is possible to efficiently dissipate heat generated by the plurality of circuit portions (chips), which are heat generating bodies, to the support substrate, and it is possible to effectively suppress the deterioration in low-light performance.

If both the circuit portion 300 and the circuit portion 310 are formed as a single chip, a semiconductor substrate is also disposed between the circuit portions, as a result of which the support substrate 500 having a low thermal conductivity cannot be disposed between the circuit portions. In this regard, if the circuit portion 300 and the circuit portion 310 are formed as separate chips as illustrated in FIG. 11B, the support substrate 500 can be disposed so as to surround each chip, so that heat can be efficiently dissipated from each chip. In addition, since only a non-defective chip can be selected and used for each circuit portion, a loss at the time of manufacturing is reduced as compared with a case where the circuit portion 300 and the circuit portion 310 are formed as a single chip.

As described above, in the semiconductor apparatus according to the present embodiment, at least one semiconductor chip is bonded to a first main surface of the first semiconductor substrate and protrudes from the first main surface of the first semiconductor substrate. The second semiconductor substrate having at least one recess is bonded to at least one of the main surface of the first semiconductor substrate and the semiconductor chip. The semiconductor chip is disposed in the recess of the second semiconductor substrate in cross-sectional view so as to be surrounded by the second semiconductor substrate in plan view. In a case where there is one chip, it is sufficient if the number of recesses of the second semiconductor substrate is one, but there may be two or more recesses. In a case where there are a plurality of chips, it is desirable that each chip is disposed in an individual recess, and it is desirable that the second semiconductor substrate has as many recesses as or more than the number of chips.

### Method for Manufacturing Semiconductor Apparatus

Next, a method for manufacturing the semiconductor apparatus 100 according to the present embodiment will be described with reference to the drawings.

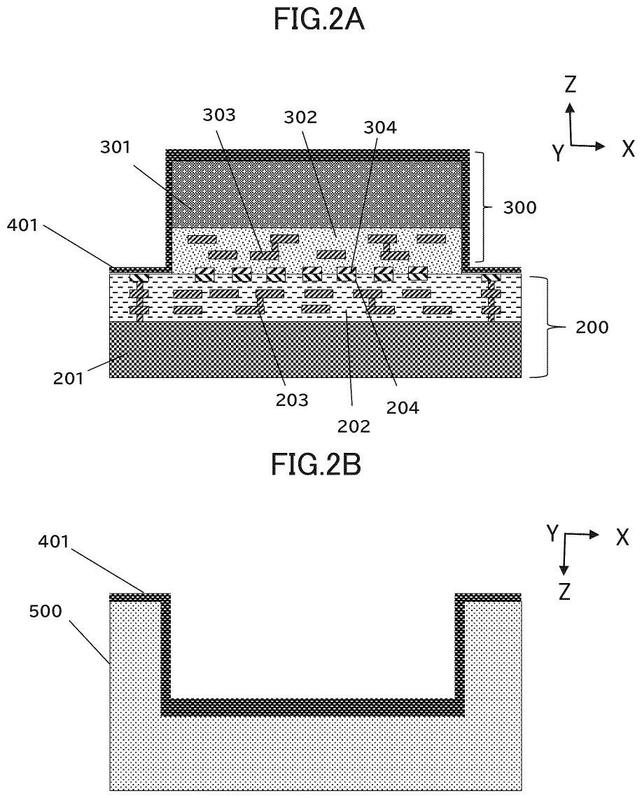

First, the imaging element 200 and the circuit portion 300 are bonded to each other (first bonding step). FIG. 2A is a schematic cross-sectional view illustrating cross sections of the imaging element 200 and the circuit portion 300 that are bonded to each other, taken along a direction perpendicular to the main surface (for example, a light receiving surface) of the imaging element 200. Although FIG. 2A illustrates a portion corresponding to one unit of the semiconductor apparatus 100 in the CoW structure, a plurality of imaging elements 200 may be formed on one semiconductor wafer, and the circuit portion 300 (chip) may be bonded to each imaging element 200.

For example, the metal layer 304 and the metal layer 204 containing Cu as the main components are disposed in the circuit portion 300 and the imaging element 200, respectively, and can be bonded by metal bonding of Cu—Cu and covalent bonding between the interlayer wiring film 202 and the interlayer wiring film 302. In some cases, a step of thinning the second semiconductor layer 301 may be performed after bonding the chips. Thereafter, the bonding layer 401 made of, for example, silicon oxide may be formed.

In addition, the support substrate 500 in which the recess is formed is prepared as illustrated in a cross section in FIG. 2B. For example, a recess (trench) is formed in a silicon substrate by using a photolithography technique and an etching technique. The trench is formed in a shape corresponding to an outer shape of the circuit portion 300 (chip). Thereafter, the bonding layer 401 made of, for example, silicon oxide may be formed. Although FIG. 2B illustrates a portion corresponding to one unit of the semiconductor apparatus 100, the support substrate 500 may be a wafer-like support substrate in which a plurality of recesses (trenches) for accommodating a plurality of circuit portions 300 (chips) are provided in one wafer. It is desirable that the support substrate 500 has a high mechanical strength and a high thermal conductivity, and a material having a thermal conductivity of 100 W/m²·K or more may be used. For example, silicon can be used, and a silicide layer having a high thermal conductivity may be provided on the surface thereof.

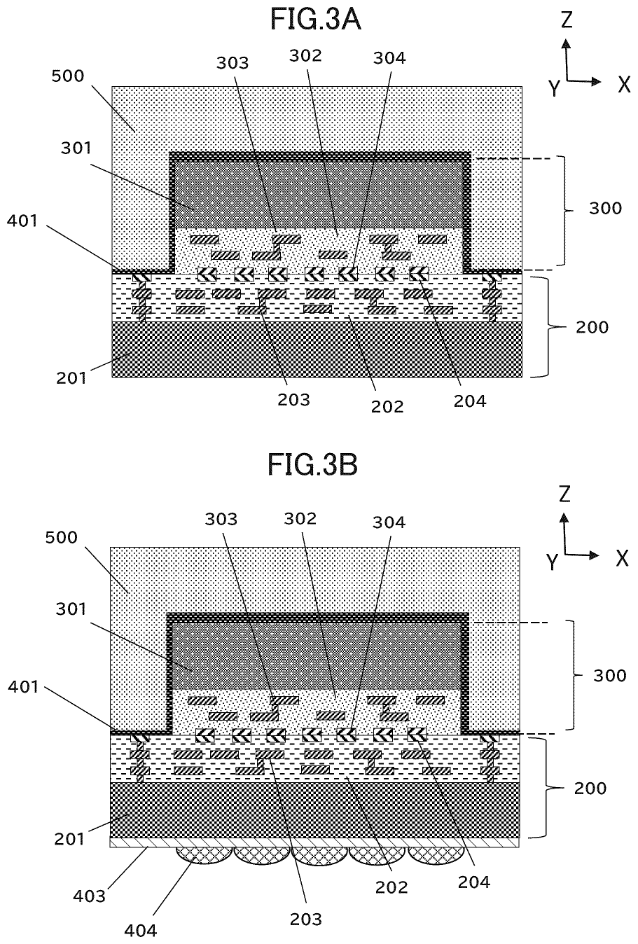

Next, as illustrated in FIG. 3A, the CoW structure in which the imaging element 200 and the circuit portion 300 are bonded to each other and the support substrate 500 are bonded to each other with the bonding layer 401 interposed therebetween (second bonding step). It is sufficient if the bonding layer 401 is formed on one or both of the CoW structure and the support substrate 500. Different materials such as silicon oxide and silicon nitride may be used for the bonding layer 401. At the time of the bonding, the circuit portion 300 (chip), which is the protrusion, and the recess of the support substrate 500 are aligned so as to face each other, and the protrusion and the recess are fitted and bonded in an aligned state. After the bonding, thinning processing of thinning the first semiconductor layer 201 to a suitable thickness is performed. A step of thinning the first semiconductor layer 201 can be performed by, for example, chemical mechanical polishing (CMP). The thinning processing may include a step of controlling the thickness by using an etching rate difference with respect to a chemical liquid caused by a difference in impurity concentration in the semiconductor layer.

It is desirable that surfaces of the support substrate 500 and the circuit portion 300 that face each other are in contact with each other without a gap in consideration of efficiency in heat dissipation from the circuit portion 300 to the support substrate 500, but the entire surfaces facing each other are not necessarily in contact with each other without a gap due to a shape variation at the time of manufacturing. Therefore, adhesion can be improved to reduce the gap by making one or both of the bonding layers 401 provided on the support substrate 500 and the circuit portion 300 sticky. The bonding layer 401 can be formed by applying spin on glass having viscosity adjusted by using, for example, a siloxane component and an alcohol solvent, and then performing annealing. The thickness of the bonding layer 401 is, for example, 3 μm or less.

According to such a bonding method, it is possible to suppress occurrence of a bonding failure and to efficiently transmit heat generated in the circuit portion 300 to the support substrate 500. That is, a decrease in manufacturing yield can be suppressed, and deterioration in low-light performance of the imaging element 200 can be reduced.

Then, as illustrated in FIG. 3B, the optical structures such as the color filter 403 and the microlens 404 are formed on the first semiconductor layer 201 which is a light receiving portion of the imaging element 200. FIG. 3B illustrates a portion corresponding to one unit of the semiconductor apparatus 100, but since a plurality of units are formed in one wafer, the respective units are separated by dicing after the optical structure is formed. That is, one unit of the semiconductor apparatus 100 described with reference to FIGS. 1A and 1B is obtained by dicing.

The semiconductor apparatus described with reference to FIGS. 11A and 11B can also be manufactured by the same procedure as described above.

### Second Embodiment

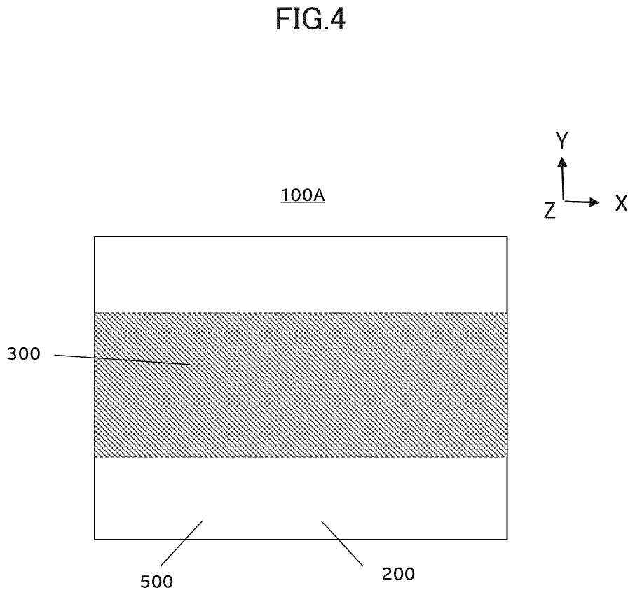

A semiconductor apparatus according to a second embodiment will be described with reference to the drawings. A description of matters common to the first embodiment will be simplified or omitted. FIG. 4 is a plan view schematically illustrating a semiconductor apparatus 100A according to the present embodiment in plan view (perspective view) when viewed from the Z direction which is a direction perpendicular to a main surface of the semiconductor apparatus 100A.

In the first embodiment, the entire periphery of the circuit portion 300 is surrounded by the support substrate 500 in plan view of the semiconductor apparatus 100 when viewed from a direction (that is, the Z direction) perpendicular to the main surface of the first semiconductor layer 201 or the second semiconductor layer 301. On the other hand, a circuit portion 300 and a support substrate 500 have the same width in the X direction, and the circuit portion 300 is sandwiched by the support substrate 500 from two directions of a +Y direction and a −Y direction in plan view of the semiconductor apparatus 100A according to the present embodiment.

In the present embodiment, two side surfaces and one main surface (a surface opposite to an imaging element 200) of the circuit portion 300 face the support substrate 500 having a higher thermal conductivity than an insulator. In addition, the imaging element 200 is bonded to the support substrate 500 having a higher thermal conductivity than the insulator on both main surfaces sandwiching the circuit portion 300 in plan view.

According to the present embodiment having such a structure, heat generated by the circuit portion 300 (chip) can be more efficiently dissipated through the support substrate 500 as compared with a case where the circuit portion 300 (chip), which is a heat generating body, is embedded in the insulator as in the related art. In addition, it is possible to efficiently dissipate heat from the imaging element 200 to the support substrate 500. That is, in a semiconductor apparatus in which a plurality of semiconductor substrates provided with semiconductor elements are bonded, it is possible to effectively suppress deterioration in low-light performance.

The semiconductor apparatus 100A according to the present embodiment is manufactured by the same manufacturing method as in the first embodiment, and a bonding layer 401 can be made sticky by using spin on glass or the like when bonding the circuit portion 300 and the imaging element 200 to the support substrate 500. The spin on glass is prepared from a siloxane component, an alcohol serving as a solvent, and the like. Adhesion can be improved to reduce the gap, and an excess bonding layer material can be efficiently discharged to the outside along a groove extending in the X direction in the support substrate 500. As a result, it is possible to suppress occurrence of a bonding failure and to efficiently transmit heat generated in the circuit portion 300 to the support substrate 500. That is, a decrease in manufacturing yield can be suppressed, and deterioration in low-light performance of the imaging element 200 can be reduced.

### Third Embodiment

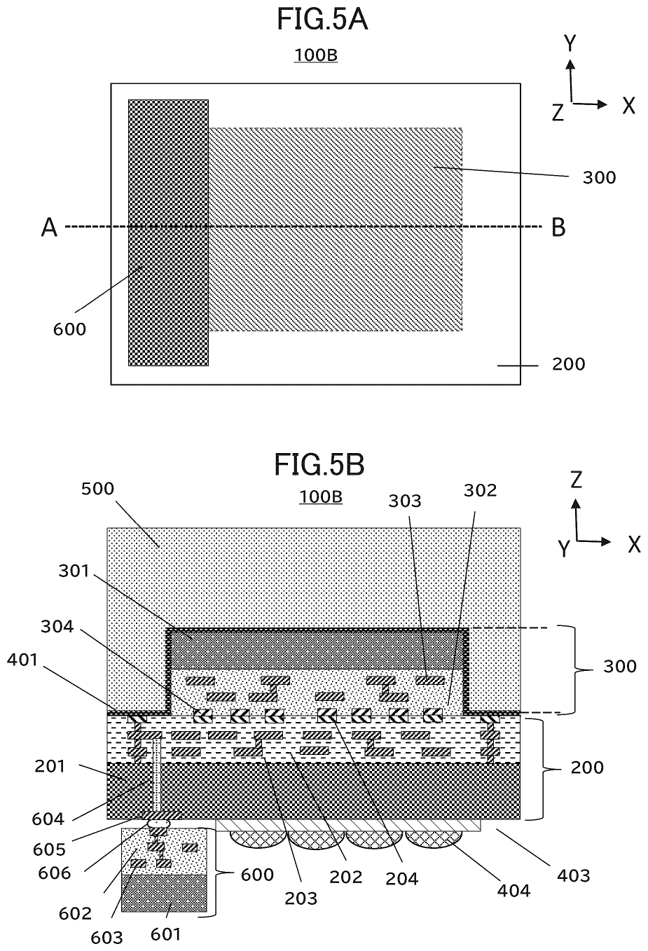

A semiconductor apparatus according to a third embodiment will be described with reference to the drawings. A description of matters common to the first embodiment will be simplified or omitted. FIG. 5A is a plan view schematically illustrating a semiconductor apparatus 100B according to the present embodiment in plan view (perspective view) when viewed from the Z direction perpendicular to a main surface of semiconductor apparatus 100B. FIG. 5B is a schematic cross-sectional view illustrating a cross section of the semiconductor apparatus 100B taken along line A-B illustrated in FIG. 5A.

The semiconductor apparatus 100B according to the present embodiment is different from the semiconductor apparatus 100 according to the first embodiment in including a circuit portion 600 (third semiconductor substrate) disposed on a main surface (second main surface) on a light receiving surface side of an imaging element 200 (first semiconductor substrate). For example, an analog circuit may be disposed in a circuit portion 300 (semiconductor chip), and a digital circuit may be disposed in the circuit portion 600 (third semiconductor substrate). Alternatively, a circuit of the semiconductor apparatus 100B can be configured such that a specific portion that generates heat in the circuit is disposed in the circuit portion 600 (third semiconductor substrate) that is at a position where an air-cooling effect is excellent. In this way, occurrence of heat generation unevenness in the circuit portion 300 (semiconductor chip) is reduced, so that uniformity of a temperature distribution in an imaging region of the imaging element 200 can be improved.

In the present embodiment, a support substrate 500 also has a larger area than the circuit portion 300 in plan view of the semiconductor apparatus 100B when viewed from a direction (that is, the Z direction) perpendicular to a main surface of a first semiconductor layer 201 or a second semiconductor layer 301. The circuit portion 300 is surrounded by the support substrate 500 in plan view. In a cross-sectional view in the direction perpendicular to the main surface of the first semiconductor layer 201 or the second semiconductor layer 301, one main surface (a main surface opposite to the imaging element 200) and side surfaces of the circuit portion 300 face the support substrate 500 with a bonding layer 401 interposed therebetween. That is, the circuit portion 300 is surrounded by the support substrate 500 having a higher thermal conductivity than an insulator except for a main surface on a side bonded to the imaging element 200. Furthermore, the main surface of the imaging element 200 is bonded to the support substrate 500 having a higher thermal conductivity than the insulator in the periphery of the circuit portion 300 in plan view.

According to the present embodiment having such a structure, heat generated by the circuit portion 300 (chip) can be more efficiently dissipated through the support substrate 500 as compared with a case where the circuit portion 300 (chip), which is a heat generating body, is embedded in the insulator as in the related art. In addition, the heat generated by the circuit portion 600 can be effectively air-cooled. That is, in a semiconductor apparatus in which a plurality of semiconductor substrates provided with semiconductor elements are bonded, it is possible to effectively suppress deterioration in low-light performance.

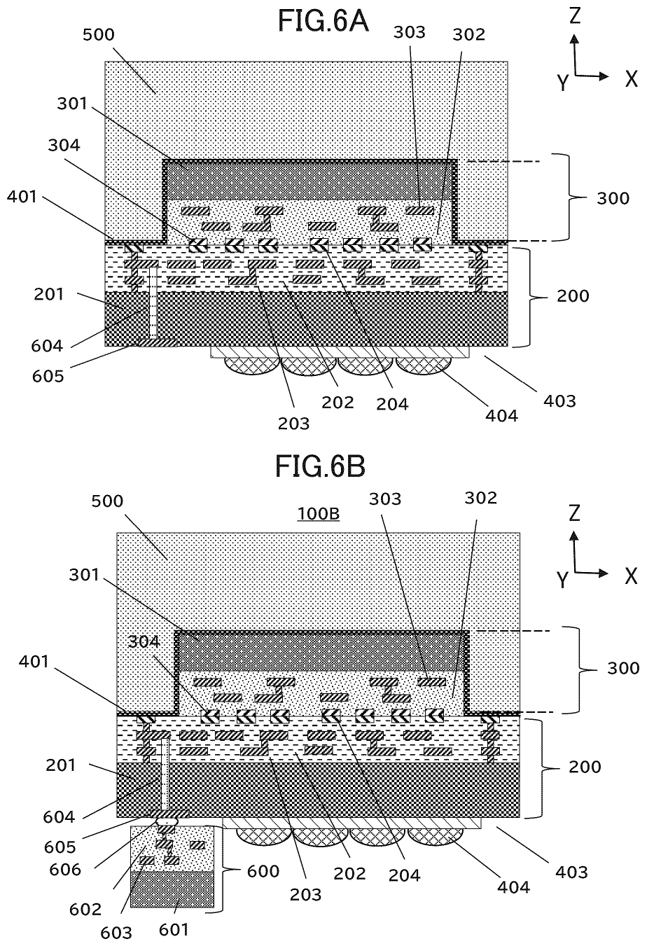

A method for manufacturing the semiconductor apparatus 100B according to the present embodiment is similar to that of the first embodiment described with reference to FIGS. 2A to 3A up to the step of bonding the imaging element 200 and the circuit portion 300. Thereafter, in the present embodiment, as illustrated in FIG. 6A, a through-via 604 is formed in the first semiconductor layer 201, and a connecting portion 605 is further formed at a tip of the through-via 604. Subsequently, optical structures such as a color filter 403 and a microlens 404 are formed on a light receiving portion of the first semiconductor layer 201.

Subsequently, as illustrated in FIG. 6B, the circuit portion 600 is bonded to the imaging element 200. The circuit portion 600 is a chip in which a third semiconductor layer 601, an interlayer wiring film 602 (interlayer insulating film), and a wiring layer 603 are stacked and integrated, and is connected to the connecting portion 605 of the imaging element 200 using, for example, a bump 606 containing Au as a main component, thereby completing the semiconductor apparatus 100B.

### Fourth Embodiment

A semiconductor apparatus according to a fourth embodiment will be described with reference to the drawings. A description of matters common to the first embodiment will be simplified or omitted. In the first embodiment, the support substrate 500 is bonded to both the imaging element 200 and the circuit portion 300 via the bonding layer 401. On the other hand, in the present embodiment, a support substrate 500 is bonded to only one of an imaging element 200 and a circuit portion 300.

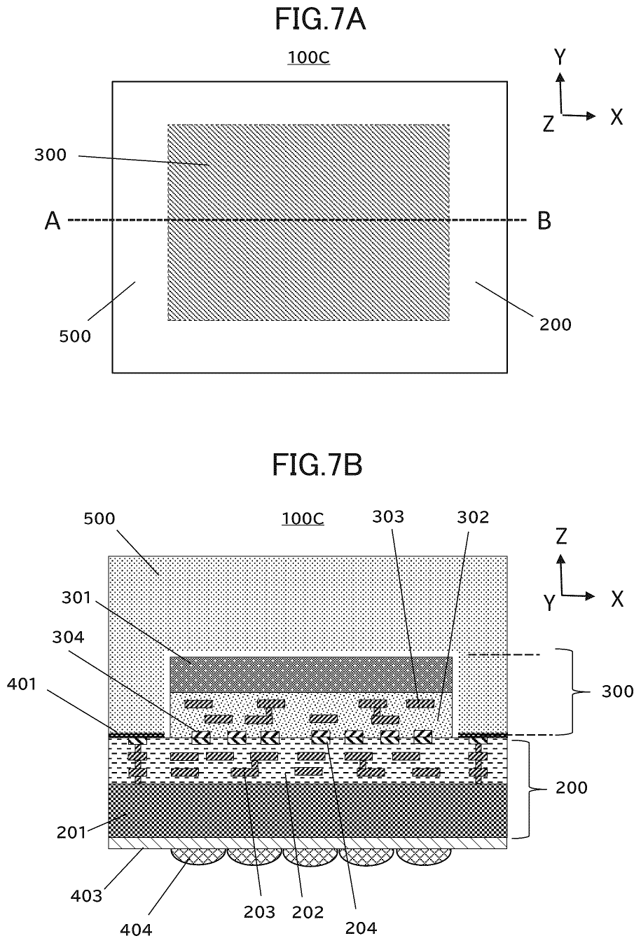

First, a mode in which the support substrate 500 is bonded only to the imaging element 200 among the imaging element 200 and the circuit portion 300 will be described. FIG. 7A is a plan view schematically illustrating a semiconductor apparatus 100C according to the present embodiment in plan view (perspective view) when viewed from the Z direction perpendicular to a main surface of the semiconductor apparatus 100C. FIG. 7B is a schematic cross-sectional view illustrating a cross section of the semiconductor apparatus 100C taken along line A-B illustrated in FIG. 7A.

The support substrate 500 is bonded to the imaging element 200 via a bonding layer 401, but is not bonded to the circuit portion 300. It is desirable that surfaces of the support substrate 500 and the circuit portion 300 that face each other are in contact with each other without a gap in consideration of efficiency in heat dissipation from the circuit portion 300 to the support substrate 500, but the entire surfaces facing each other do not have to be in contact with each other due to a shape variation at the time of manufacturing. In some cases, the gap may be provided between the support substrate 500 and the circuit portion 300 in order to secure a clearance corresponding to a shape error due to manufacturing variations. Alternatively, a thermally conductive material such as thermally conductive grease may be disposed in the gap.

In the present embodiment, the support substrate 500 also has a larger area than the circuit portion 300 in plan view of the semiconductor apparatus 100C when viewed from a direction (that is, the Z direction) perpendicular to a main surface of a first semiconductor layer 201 or a second semiconductor layer 301. The circuit portion 300 is surrounded by the support substrate 500 in plan view. In a cross-sectional view in the direction perpendicular to the main surface of the first semiconductor layer 201 or the second semiconductor layer 301, one main surface (a main surface opposite to the imaging element 200) and side surfaces of the circuit portion 300 face the support substrate 500. That is, the circuit portion 300 is surrounded by the support substrate 500 having a higher thermal conductivity than an insulator except for a surface that is in contact with (bonded to) the imaging element 200. Furthermore, the imaging element 200 is bonded to the support substrate 500 having a higher thermal conductivity than the insulator in the periphery of the circuit portion 300 in plan view.

According to the present embodiment having such a structure, heat generated by the circuit portion 300 (chip) can be more efficiently dissipated through the support substrate 500 as compared with a case where the circuit portion 300 (chip), which is a heat generating body, is embedded in the insulator as in the related art. In addition, it is possible to efficiently dissipate heat from the imaging element 200 to the support substrate 500. That is, in a semiconductor apparatus in which a plurality of semiconductor substrates provided with semiconductor elements are bonded, it is possible to effectively suppress deterioration in low-light performance.

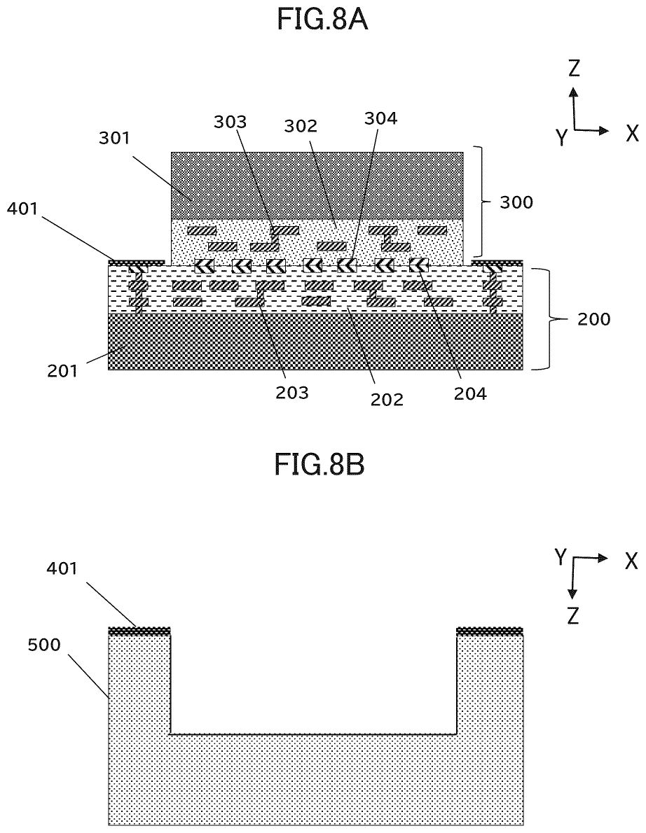

A method for manufacturing the semiconductor apparatus 100C according to the present embodiment is different from that of the first embodiment described with reference to FIGS. 2A and 2B in terms of a position where the bonding layer 401 is provided. In the present embodiment, the position where the bonding layer 401 is provided is as illustrated in FIGS. 8A and 8B. As illustrated, the bonding layer 401 is provided at a position where the imaging element 200 and the support substrate 500 face each other, but the bonding layer 401 is not provided at a position where the circuit portion 300 and the support substrate 500 face each other.

As illustrated in FIG. 8A, the bonding layer 401 made of silicon oxide or the like is formed at a part of the imaging element 200 (wafer), and then the circuit portion 300 (chip) is bonded. In addition, as illustrated in FIG. 8B, a recess and the bonding layer 401 made of silicon oxide or the like are formed on the support substrate 500 by using, for example, a photolithography technique and an etching technique. A shape of the recess corresponds to a shape of the circuit portion 300 (chip). It is sufficient if the bonding layer 401 has a thickness sufficient for bonding, and the bonding layer 401 is formed to have a thickness of, for example, 10 nm or more and 1 μm or less.

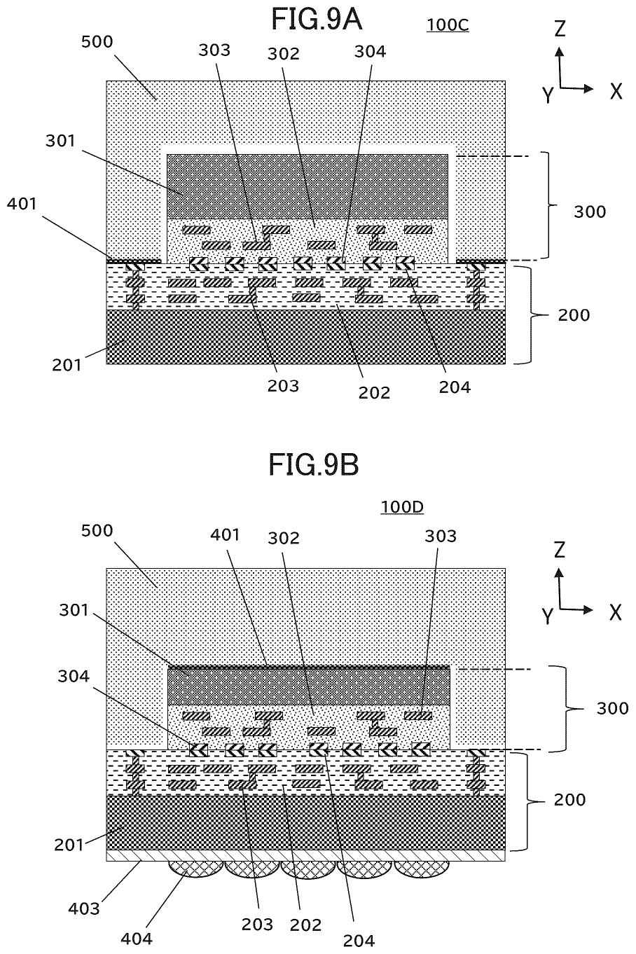

Next, as illustrated in FIG. 9A, a CoW structure in which the imaging element 200 and the circuit portion 300 are bonded to each other and the support substrate 500 are bonded to each other with the bonding layer 401 interposed therebetween. It is sufficient if the bonding layer 401 is formed on one or both of the imaging element 200 and the support substrate 500. That is, the circuit portion 300 (chip), which is a protrusion, is aligned so as to face the recess of the support substrate 500, and the protrusion and the recess are fitted to bond the imaging element 200 and the support substrate 500. After the bonding, thinning processing of thinning the first semiconductor layer 201 to a suitable thickness is performed. A step of thinning the first semiconductor layer can be performed by, for example, CMP. The thinning processing may include a step of controlling the thickness by using an etching rate difference with respect to a chemical liquid caused by a difference in impurity concentration in the semiconductor layer. In order to prevent the support substrate 500 and the circuit portion 300 from mechanically excessively interfering with each other even if manufacturing variations occur, a clearance may be secured by setting the gap between the recess of the support substrate 500 and the circuit portion 300. As a result, stress on the circuit portion 300 (chip) can be alleviated, and a metal bonding failure between the circuit portion 300 and the imaging element 200 can be suppressed. Furthermore, a step of forming optical structures such as a color filter 403 and a microlens 404 on a light receiving portion of the imaging element 200 is similar to that in the first embodiment.

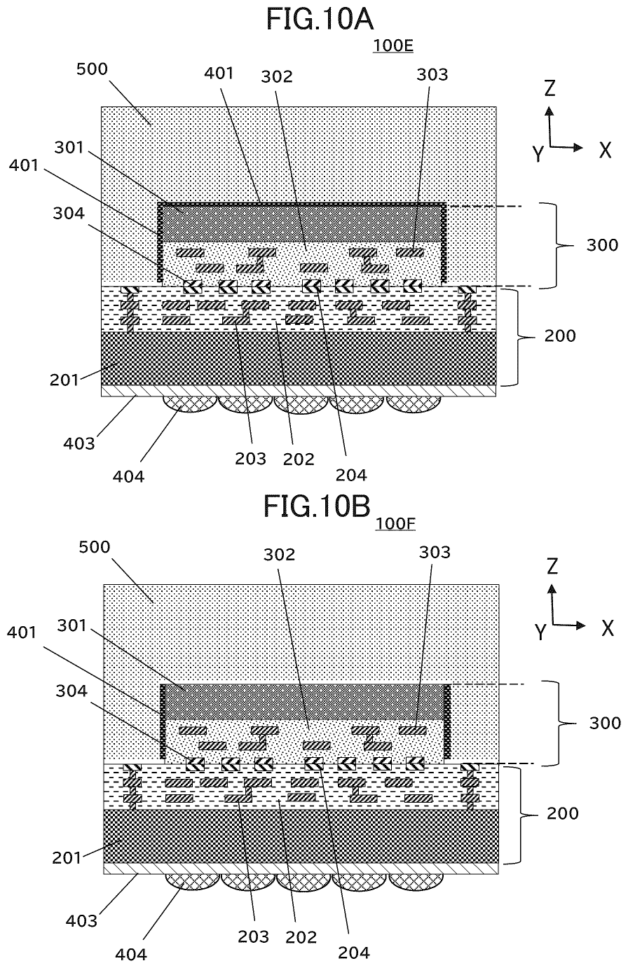

Next, a mode in which the support substrate 500 is bonded only to the circuit portion 300 among the imaging element 200 and the circuit portion 300 will be described using three examples. FIGS. 9B, 10A, and 10B illustrate schematic cross-sectional views of the respective examples.

A semiconductor apparatus 100D illustrated in FIG. 9B is an example in which, among exterior surfaces of a circuit portion 300 (chip), a surface overlapping a support substrate 500 in plan view is bonded to the support substrate 500 via a bonding layer 401. That is, one main surface (a main surface opposite to an imaging element 200) of the circuit portion 300 is bonded to the support substrate 500 via the bonding layer 401.

A semiconductor apparatus 100E illustrated in FIG. 10A is an example in which exterior surfaces of a circuit portion 300 (chip) are bonded to a support substrate 500 via a bonding layer 401 except for a surface that is in contact with (bonded to) an imaging element 200. That is, one main surface (a main surface opposite to the imaging element 200) and side surfaces of the circuit portion 300 are bonded to the support substrate 500 via the bonding layer 401.

A semiconductor apparatus 100F illustrated in FIG. 10B is an example in which, among exterior surfaces of a circuit portion 300 (chip), side surfaces are bonded to a support substrate 500 via bonding layers 401.

According to the present embodiment having such an exemplified structure, heat generated by the circuit portion 300 (chip) can be more efficiently dissipated through the support substrate 500 as compared with a case where the circuit portion 300 (chip), which is a heat generating body, is embedded in the insulator as in the related art. That is, in a semiconductor apparatus in which a plurality of semiconductor substrates provided with semiconductor elements are bonded, it is possible to effectively suppress deterioration in low-light performance. In addition, since no bonding layer is disposed between the imaging element 200 and the support substrate 500, a parasitic capacitance between a wiring layer 203 and the support substrate 500 can be reduced.

### Fifth Embodiment

A semiconductor apparatus according to a fifth embodiment will be described with reference to the drawings. A description of matters common to the first embodiment will be simplified or omitted. In the first embodiment, the circuit portion 300 is not connected to the support substrate 500 via wiring layers 303 and 203. On the other hand, in the present embodiment, a circuit portion 300 is connected to a support substrate 500 via the wiring layers 303 and 203.

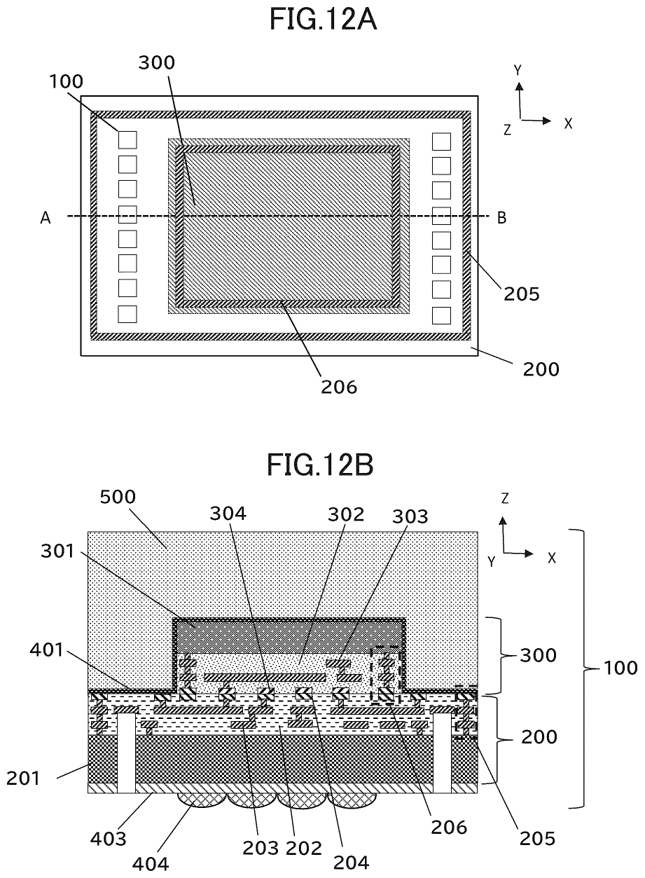

FIG. 12A is a plan view schematically illustrating a semiconductor apparatus 100G according to the present embodiment in plan view (perspective view) when viewed from the Z direction perpendicular to a main surface of the semiconductor apparatus 100G. FIG. 12B is a schematic cross-sectional view illustrating a cross section of the semiconductor apparatus 100G taken along line A-B illustrated in FIG. 12A. Note that the circuit portion 300 included in the semiconductor apparatus 100G includes a second guard portion 206. The second guard portion 206 has a function of suppressing entry of moisture from the outside of the circuit portion 300 to the inside of the circuit portion 300. As illustrated in FIG. 12A, the second guard portion 206 is disposed along an outer periphery of the circuit portion 300 in plan view.

In the present embodiment, the circuit portion 300 is connected to the support substrate 500 in addition to an imaging element 200 via the wiring layers 303 and 203. In addition, As the wiring layer 303 is not connected to a second semiconductor layer 301, and an area of the wiring layer 303 is increased, heat generated by the second semiconductor layer 301 is more easily released to the support substrate 500 while blocking heat transferred from the second semiconductor layer 301 to a first semiconductor layer 201. Therefore, deterioration in low-light performance can be expected to be reduced. In addition, by adjusting routing of the wiring layer 203, heat from the second semiconductor layer 301 is made uniform in a planar direction, and temperature unevenness of the first semiconductor layer 201 is reduced, so that unevenness of the low-light performance due to the arrangement of the second semiconductor layer 301 can be reduced.

In the present embodiment, the wiring layer 303 may have a structure connected to the second semiconductor layer 301. In this case, the wiring layer 303 connected to the second semiconductor layer 301 has a structure connected to the support substrate 500 via a metal layer 204 and the wiring layer 203.

The second semiconductor layer 301 may be connected to the support substrate 500 via the second guard portion 206 and the wiring layer 203. In this case, the heat generated by the second semiconductor layer 301 is also more easily released to the support substrate 500, so that the deterioration in low-light performance can be reduced.

According to the present embodiment having such an exemplified structure, heat generated by the second semiconductor layer 301 can be more efficiently dissipated via the support substrate 500 as compared with a case where the second semiconductor layer 301, which is a heat generating body, is electrically connected only to the first semiconductor layer 201 as in the related art. That is, it is possible to effectively suppress the deterioration in low-light performance.

### Sixth Embodiment

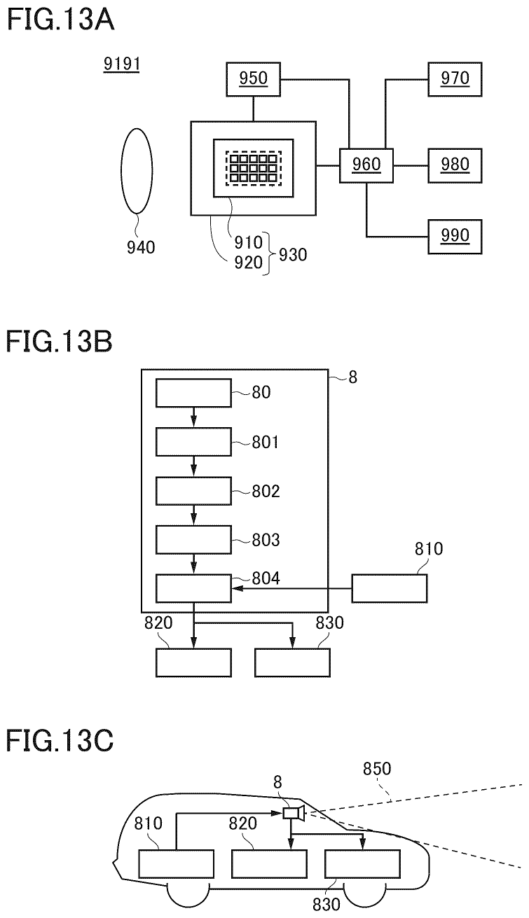

As a sixth embodiment, equipment including the semiconductor apparatus (solid-state imaging apparatus) according to any one of the above-described embodiments will be described. FIG. 13A is a schematic diagram for describing equipment 9191 including a semiconductor apparatus 930 according to the above-described embodiment. The equipment 9191 including the semiconductor apparatus 930 will be described in detail.

The semiconductor apparatus 930 includes a semiconductor device 910 in which a first chip serving as a photoelectric conversion apparatus and a second chip including at least one of a memory circuit and a logic circuit are integrated. In addition to the semiconductor device 910, the semiconductor apparatus 930 may further include a package 920 that houses the semiconductor device 910. The package 920 can include a base to which the semiconductor device 910 is fixed and a lid such as glass that faces the semiconductor device 910. The package 920 can further include a bonding member such as a bonding wire or a bump that connects a terminal provided on the base and a terminal provided on the semiconductor device 910.

The equipment 9191 can include at least one of an optical apparatus 940, a control apparatus 950, a processing apparatus 960, a display apparatus 970, a storage apparatus 980, and a mechanical apparatus 990. The optical apparatus 940 is, for example, a lens, a shutter, or a mirror provided corresponding to the semiconductor apparatus 930. The control apparatus 950 controls the semiconductor apparatus 930. The control apparatus 950 is, for example, a semiconductor apparatus such as an application specific integrated circuit (ASIC).

The processing apparatus 960 processes a signal output from the semiconductor apparatus 930. The processing apparatus 960 is a semiconductor apparatus such as a central processing unit (CPU) or an ASIC for configuring an analog front end (AFE) or a digital front end (DFE). The display apparatus 970 is an EL display apparatus or a liquid crystal display apparatus that displays information (image) obtained by the semiconductor apparatus 930. The storage apparatus 980 is a magnetic device or a semiconductor device that stores information (image) obtained by the semiconductor apparatus 930. The storage apparatus 980 is a volatile memory such as a static random-access memory (SRAM) or a dynamic random-access memory (DRAM), or a nonvolatile memory such as a flash memory or a hard disk drive.

The mechanical apparatus 990 includes a movable unit such as a motor or an engine, or a propulsion unit. In the equipment 9191, a signal output from the semiconductor apparatus 930 is displayed on the display apparatus 970 or is transmitted to the outside by a communication apparatus (not illustrated) included in the equipment 9191. Therefore, the equipment 9191 preferably further includes the storage apparatus 980 and the processing apparatus 960 separately from a storage circuit and an arithmetic circuit of the semiconductor apparatus 930. The mechanical apparatus 990 may be controlled based on a signal output from the semiconductor apparatus 930.

Furthermore, the equipment 9191 is suitable for electronic equipment such as an information terminal (for example, a smartphone or a wearable terminal) having an imaging function or a camera (for example, an interchangeable lens camera, a compact camera, a video camera, or a surveillance camera). The mechanical apparatus 990 in the camera can drive components of the optical apparatus 940 for zooming, focusing, and shutter operations. Alternatively, the mechanical apparatus 990 in the camera can move the semiconductor apparatus 930 for a vibration-proof operation.

Furthermore, the equipment 9191 may be transportation equipment such as a vehicle, a ship, or a flying body. The mechanical apparatus 990 in the transportation equipment can be used as a movement apparatus. The equipment 9191 serving as transportation equipment is suitable for transporting the semiconductor apparatus 930 and assisting and/or automating driving (steering) by the imaging function. The processing apparatus 960 for assisting and/or automating the driving (steering) can perform processing for operating the mechanical apparatus 990 serving as the movement apparatus based on information obtained by the semiconductor apparatus 930. Alternatively, the equipment 9191 may be medical equipment such as an endoscope, measurement equipment such as a distance measurement sensor, analytical equipment such as an electron microscope, office equipment such as a copying machine, or industrial equipment such as a robot. According to the above-described embodiment, since heat is efficiently dissipated from a chip of an image sensor, it is possible to stably acquire an image with favorable characteristics.

Therefore, if the semiconductor apparatus 930 according to the present embodiment is used for the equipment 9191, the value of the equipment can also be improved. For example, it is possible to obtain excellent performance when the semiconductor apparatus 930 is mounted on the transportation equipment and performs imaging of the outside of the transportation equipment or measurement of an external environment. Therefore, in manufacturing and selling the transportation equipment, it is advantageous to determine to mount the semiconductor apparatus according to the present embodiment on the transportation equipment in order to enhance the performance of the transportation equipment itself. In particular, the semiconductor apparatus 930 is suitable for transportation equipment that performs driving assistance and/or automated driving of the transportation equipment by using information obtained by the semiconductor apparatus. Implementation in a vehicle, a ship, a flying body, and the like is not limited to application to equipment practically used for transportation purposes, and can be suitably applied to, for example, a drone or the like that performs aerial imaging for various purposes including inspection of buildings and agricultural facilities, monitoring of natural phenomena, and the like.

A photoelectric conversion system and a mobile body according to the present embodiment will be described with reference to FIGS. 13B and 13C. FIG. 13B illustrates an example of the photoelectric conversion system related to an in-vehicle camera. A photoelectric conversion system 8 includes a photoelectric conversion apparatus 80. The photoelectric conversion apparatus 80 is a photoelectric conversion apparatus serving as an electronic component described in the above-described embodiment. The photoelectric conversion system 8 includes an image processing unit 801 that performs image processing on a plurality of pieces of image data acquired by the photoelectric conversion apparatus 80, and a parallax acquisition unit 802 that calculates a parallax (a phase difference of a parallax image) from the plurality of pieces of image data acquired by the photoelectric conversion system 8. Furthermore, the photoelectric conversion system 8 includes a distance acquisition unit 803 that calculates a distance to a target object based on the calculated parallax, and a collision determination unit 804 that determines whether or not there is a possibility of collision based on the calculated distance. Here, the parallax acquisition unit 802 and the distance acquisition unit 803 are examples of a distance information acquisition unit that acquires distance information to the target object. That is, the distance information is information regarding the parallax, a defocus amount, the distance to the target object, and the like. The collision determination unit 804 may determine the possibility of collision by using any one of these pieces of distance information. The distance information acquisition unit may be implemented by dedicated hardware or may be implemented by a software module. Alternatively, the distance information acquisition unit may be implemented by a field programmable gate array (FPGA), an application specific integrated circuit (ASIC), or the like.

The photoelectric conversion system 8 is connected to a vehicle information acquisition apparatus 810, and can acquire vehicle information such as a vehicle speed, a yaw rate, and a steering angle. In addition, the photoelectric conversion system 8 is connected to a control ECU 820 which is a control apparatus that outputs a control signal for generating a braking force on the vehicle based on a determination result of the collision determination unit 804. The photoelectric conversion system 8 is also connected to a warning apparatus 830 that issues a warning to a driver based on the determination result of the collision determination unit 804. For example, in a case where the determination result of the collision determination unit 804 indicates that the possibility of collision is high, the control ECU 820 performs vehicle control to avoid collision and reduce damage by applying a brake, returning an accelerator, reducing an engine output, or the like. The warning apparatus 830 issues a warning to a user by emitting warnings such as sound, displaying warning information on a screen of a car navigation system or the like, providing vibrations to a seat belt or a steering wheel, or the like.

In the present embodiment, the photoelectric conversion system 8 images the periphery of the vehicle, for example, an area in front of or behind the vehicle. FIG. 13C illustrates the photoelectric conversion system in a case of imaging the area (imaging range 850) in front of the vehicle. The vehicle information acquisition apparatus 810 sends an instruction to the photoelectric conversion system 8 or the photoelectric conversion apparatus 80. With such a configuration, accuracy of distance measurement can be further improved.

In the above description, an example of performing control to prevent collision with another vehicle has been described, but the present technology is also applicable to control for performing automated driving following another vehicle, control for performing automated driving so as not to stray from a lane, and the like. Furthermore, the photoelectric conversion system is not limited to the vehicle such as an own vehicle, and can be applied to a mobile body (mobile apparatus) such as a ship, an aircraft, or an industrial robot, for example. In addition, the present technology can be applied not only to a mobile body but also to equipment that widely uses object recognition, such as an intelligent transport system (ITS). According to the above-described embodiment, since heat is efficiently dissipated from a chip of an image sensor to a support substrate, it is possible to stably acquire an image with favorable characteristics.

The equipment according to the present embodiment can include at least one of the optical apparatus corresponding to the semiconductor apparatus according to any one of the above-described embodiments, the control apparatus that controls the semiconductor apparatus, and the processing apparatus that processes information obtained from the semiconductor apparatus. Alternatively, the equipment may include at least one of the display apparatus that displays information obtained from the semiconductor apparatus, the storage apparatus that stores information obtained from the semiconductor apparatus, and the mechanical apparatus that operates based on information obtained from the semiconductor apparatus.

### Other Embodiments

Note that the present invention is not limited to the embodiments described above, and many modifications can be made within the technical idea of the present invention. For example, all or some of the different embodiments described above may be combined and implemented.

For example, in the above-described embodiments, one or two chips having a small projection area are integrated so as to be included in a first chip (wafer) having a large projection area in plan view, but three or more chips may be integrated with the first chip. It is preferable that at least the same number of recesses as the number of chips are arranged in a support member having a high thermal conductivity, and each chip is individually disposed in each recess.

In the third embodiment, the circuit portion 600 is provided on the main surface on the light receiving surface side of the imaging element 200 separately from the circuit portion 300. However, also in other embodiments, the circuit portion 600 can be provided on the main surface on the light receiving surface side.

The photoelectric conversion apparatus to which the present invention is applied is not limited to a specific form, and for example, the light receiving portion may be any one of a front-illuminated type or a back-illuminated type. An image signal output from the photoelectric conversion apparatus may be an analog signal or a digital signal. Furthermore, the application of the photoelectric conversion apparatus according to the embodiment is not limited to imaging, and the photoelectric conversion apparatus is also applicable to a distance measurement apparatus (an apparatus for focus detection, distance measurement using time of flight (TOF), or the like), a photometric apparatus (an apparatus for measuring an incident light quantity or the like), or the like.

According to the present disclosure, it is possible to provide a semiconductor apparatus in which a plurality of semiconductor substrates provided with semiconductor elements are bonded, in which heat is less likely to be trapped and deterioration in image quality is suppressed.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-50286, filed Mar. 26, 2024, and Japanese Patent Application No. 2025-005451, filed Jan. 15, 2025, which are hereby incorporated by reference herein in their entirety.

What is claimed is:

1. A semiconductor apparatus comprising: a first semiconductor substrate; a second semiconductor substrate; and at least one semiconductor chip, wherein
the at least one semiconductor chip is bonded to the first semiconductor substrate so as to protrude from a first main surface of the first semiconductor substrate,
the second semiconductor substrate having at least one recess is bonded to at least one of a part of the first main surface and the at least one semiconductor chip,
the at least one semiconductor chip is disposed in the at least one recess, and
the at least one semiconductor chip is connected to the second semiconductor substrate via a wiring included in the first semiconductor substrate.

2. The semiconductor apparatus according to claim 1, wherein
the second semiconductor substrate has a higher thermal conductivity than silicon oxide.

3. The semiconductor apparatus according to claim 1, wherein
a thermal conductivity of the second semiconductor substrate is 100 W/m²·K or higher.

4. The semiconductor apparatus according to claim 1, wherein
a main component of the second semiconductor substrate is silicon or silicide.

5. The semiconductor apparatus according to claim 1, wherein
the first semiconductor substrate and the second semiconductor substrate are bonded to each other.

6. The semiconductor apparatus according to claim 1, wherein
the at least one semiconductor chip and the second semiconductor substrate are bonded to each other.

7. The semiconductor apparatus according to claim 1, wherein
the first semiconductor substrate and the second semiconductor substrate are bonded to each other, and the at least one semiconductor chip and the second semiconductor substrate are bonded to each other.

8. The semiconductor apparatus according to claim 1, wherein
the second semiconductor substrate is bonded to at least one of the part of the first main surface and the at least one semiconductor chip via a bonding layer.

9. The semiconductor apparatus according to claim 8, wherein
the bonding layer contains silicon oxide or silicon nitride.

10. The semiconductor apparatus according to claim 8, wherein
a thickness of the bonding layer is 10 nm or more and 1 μm or less.

11. The semiconductor apparatus according to claim 1,
further comprising a third semiconductor substrate bonded to a second main surface of the first semiconductor substrate that is opposite to the first main surface.

12. The semiconductor apparatus according to claim 1, wherein
the wiring included in the first semiconductor substrate and a wiring included in the at least one semiconductor chip are electrically connected by metal bonding.

13. The semiconductor apparatus according to claim 1, wherein
the first semiconductor substrate includes a photodiode.

14. The semiconductor apparatus according to claim 1, wherein
at least one of a color filter and a microlens is provided on the first semiconductor substrate.

15. The semiconductor apparatus according to claim 1, wherein
the at least one semiconductor chip includes a circuit portion.

16. The semiconductor apparatus according to claim 1, wherein
the second semiconductor substrate is a support substrate.

17. The semiconductor apparatus according to claim 1, wherein
the first semiconductor substrate includes an imaging element, and the at least one semiconductor chip is a chip including at least one of a memory circuit and a logic circuit.

18. Equipment comprising:
the semiconductor apparatus according to claim 1; and
at least one of
an optical apparatus corresponding to the semiconductor apparatus,
a control apparatus configured to control the semiconductor apparatus,
a processing apparatus configured to process information obtained from the semiconductor apparatus,
a display apparatus configured to display information obtained from the semiconductor apparatus,
a storage apparatus configured to store information obtained from the semiconductor apparatus, and
a mechanical apparatus configured to operate based on information obtained from the semiconductor apparatus.

19. A semiconductor wafer comprising a wiring, wherein
at least one semiconductor chip is bonded to the semiconductor wafer so as to protrude from a main surface of the semiconductor wafer,
a second semiconductor substrate having at least one recess is bonded to at least one of a part of the main surface and the at least one semiconductor chip,
the at least one semiconductor chip is disposed in the at least one recess, and
the at least one semiconductor chip is connected to the second semiconductor substrate via the wiring included in the semiconductor wafer.

20. A method for manufacturing a semiconductor apparatus, the method comprising:
a first bonding step of bonding at least one semiconductor chip to a first semiconductor substrate so as to protrude from a first main surface of the first semiconductor substrate;
a step of forming at least one recess in a second semiconductor substrate; and
a second bonding step of bonding the second semiconductor substrate to at least one of a part of the first main surface and the at least one semiconductor chip in a state in which the first semiconductor substrate and the second semiconductor substrate are aligned such that the at least one semiconductor chip bonded to the first semiconductor substrate is disposed in the at least one recess,
wherein in the second bonding step, the at least one semiconductor chip is connected to the second semiconductor substrate via a wiring included in the first semiconductor substrate.

21. The method according to claim 20, wherein
the second semiconductor substrate has a higher thermal conductivity than that of silicon oxide.

22. The method according to claim 20, wherein
a thermal conductivity of the second semiconductor substrate is 100 W/m²·K or higher.

23. The method according to claim 20, wherein
a main component of the second semiconductor substrate is silicon or silicide.

24. The method according to claim 20, wherein
in the second bonding step, the second semiconductor substrate is bonded to the part of the first main surface.

25. The method according to claim 20, wherein
in the second bonding step, the second semiconductor substrate is bonded to the at least one semiconductor chip.

26. The method according to claim 20, wherein
in the second bonding step, the second semiconductor substrate is bonded to both the part of the first main surface and the at least one semiconductor chip.

27. The method according to claim 20, wherein
in the second bonding step, the second semiconductor substrate is bonded to at least one of the part of the first main surface and the semiconductor chip via a bonding layer.

28. The method according to claim 27, wherein
the bonding layer contains silicon oxide or silicon nitride.
